(19) United States
(12) Patent Application Publication
(10) Pub. No.: US 2025/0226035 A1
(43) Pub. Date: Jul. 10, 2025

(54) ERASE DISTRIBUTION TIGHTENING TO IMPROVE READ BUDGET WINDOW IN A MEMORY SUB-SYSTEM

(71) Applicant: Micron Technology, Inc., Boise, ID (US)

(72) Inventors: Murong Lang, San Jose, CA (US); Hanping Chen, San Jose, CA (US); Peng Zhang, Los Altos, CA (US); Zhenming Zhou, San Jose, CA (US); Jun Wan, San Jose, CA (US)

(21) Appl. No.: 18/977,030

(22) Filed: Dec. 11, 2024

Related U.S. Application Data
(60) Provisional application No. 63/619,400, filed on Jan. 10, 2024.

(51) Int. Cl. G11C 16/10; G11C 16/08; G11C 16/34

(52) U.S. Cl. CPC G11C 16/102; G11C 16/08; G11C 16/349

(57) ABSTRACT

An erase operation on a block of a memory device is performed. Whether a program after erase mode is enabled is determined. A programming operation associated with the program after erase mode is performed on an erase distribution of the block responsive to determining that the program after erase mode is enabled.

### RELATED APPLICATIONS

This application claims the benefit of U.S. Provisional Paten Application No. 63/619,400, filed Jan. 10, 2024, which is incorporated by reference herein.

### TECHNICAL FIELD

Embodiments of the disclosure relate generally to memory sub-systems, and more specifically, relate to erase distribution tightening to improve read budget window in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system in accordance with some embodiments of the present disclosure.

FIG. 1B is a block diagram of a memory device in communication with a memory sub-system controller of a memory sub-system in accordance with some embodiments of the present disclosure.

FIG. 2A-C are schematics of portions of an array of memory cells as could be used in a memory of the type described with reference to FIG. 1B in accordance with some embodiments of the present disclosure.

FIG. 3 is a block schematic of a portion of an array of memory cells as could be used in a memory of the type described with reference to FIG. 1B in accordance with some embodiments of the present disclosure.

FIG. 4 is a conceptual depiction of threshold voltage distributions of multiple memory cells of a memory array in accordance with some embodiments of the present disclosure.

FIG. 5 is a conceptual depiction of a threshold voltage distribution of multiple memory cells at one stage following programming in accordance with some embodiments of the present disclosure.

FIG. 6 is a flow diagram of an example method for erase distribution tightening to improve read budget window in accordance with some embodiments of the present disclosure.

FIG. 7 is a flow diagram of an example method for erase distribution tightening to improve read budget window in accordance with some embodiments of the present disclosure.

FIG. 8 is a block diagram of an example computer system in which embodiments of the present disclosure may operate.

### DETAILED DESCRIPTION

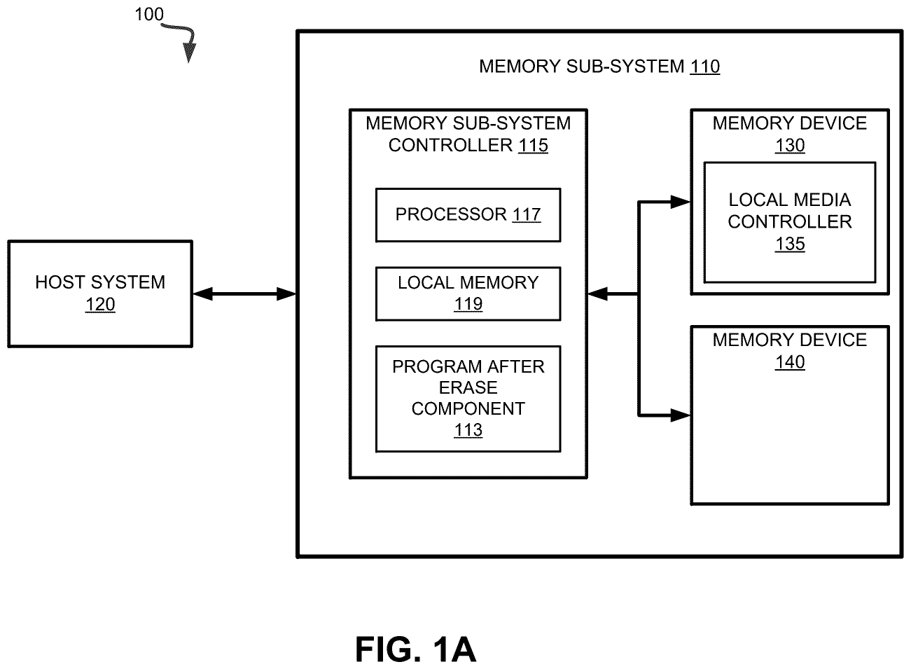

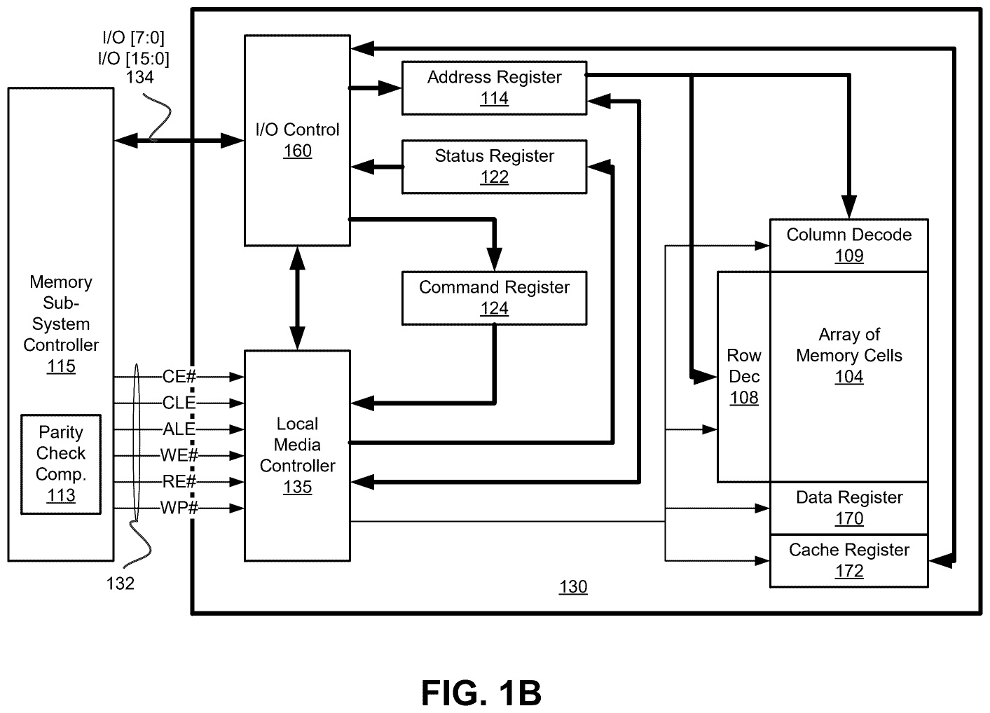

Aspects of the present disclosure are directed to erase distribution tightening to improve read budget window in a memory sub-system. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 1A. A non-volatile memory device is a package of one or more dies. Each die can consist of one or more planes. For some types of non-volatile memory devices (e.g., NAND devices), each plane consists of a set of physical blocks. Each block consists of a set of pages. Each page consists of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple cells arranged in a two-dimensional or a three-dimensional grid. Memory cells can be formed onto a silicon wafer in an array of columns connected by conductive lines (also hereinafter referred to as bitlines, or BLs) and rows connected by conductive lines (also hereinafter referred to as wordlines or WLs). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane.

A memory cell (“cell”) can be programmed (written to) by applying a certain voltage to the cell, which results in an electric charge being held by the cell. For example, a voltage signal V_{CG} that can be applied to a control electrode of the cell to open the cell to the flow of electric current across the cell, between a source electrode and a drain electrode. More specifically, for each individual cell (having a charge Q stored thereon) there can be a threshold control gate voltage Vₜ (also referred to as the “threshold voltage”) such that the source-drain electric current is low for the control gate voltage (V_{CG}) being below the threshold voltage, V_{CG}<Vₜ. The current increases substantially once the control gate voltage has exceeded the threshold voltage, V_{CG}>Vₜ. Because the actual geometry of the electrodes and gates varies from cell to cell, the threshold voltages can be different even for cells implemented on the same die. The cells can, therefore, be characterized by a distribution P of the threshold voltages, P(Q,Vₜ)=dW/dVₜ, where dW represents the probability that any given cell has its threshold voltage within the interval [Vₜ, Vₜ+dVₜ] when charge Q is placed on the cell.

A memory device can exhibit threshold voltage distributions P(Q, Vₜ) that are narrow compared with the working range of control voltages tolerated by the cells of the device. Accordingly, multiple non-overlapping distributions P(Qₖ, Vₜ) (“valleys”) can be fit into the working range allowing for storage and reliable detection of multiple values of the charge Qₖ, k=1, 2, 3 . . . . The distributions (valleys) are interspersed with voltage intervals (“valley margins”) where none (or very few) of the cells of the device have their threshold voltages. Such valley margins can, therefore, be used to separate various charge states Qₖ—the logical state of the cell can be determined by detecting, during a read operation, between which two valley margins the respective threshold voltage Vₜ of the cell resides. This effectively allows a single memory cell to store multiple bits of information: a memory cell operated with 2N−1 well-defined valley margins and 2N valleys is capable of reliably storing N bits of information. Specifically, the read operation can be performed by comparing the measured threshold voltage Vₜ exhibited by the memory cell to one or more reference voltage levels corresponding to known valley margins (e.g., centers of the margins) of the memory device in order to distinguish between the multiple logical programming levels and determine the programming state of the cell.

One type of cell is a single level cell (SLC), which stores 1 bit per cell and defines 2 logical states (“states”) (“1” or “L0” and “0” or “L1”) each corresponding to a respective Vₜ level. For example, the “1” state can be an erased state and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”) each corresponding to a respective Vₜ level. For example, the “11” state can be an erased state and the “01”, “10” and “00” states can each be a respective programmed state. Another type of cell is a triple level cell (TLC), which stores 3 bits per cell and defines 8 states (“111” or “L0”, “110” or “L1”, “101” or “L2”, “100” or “L”, “011” or “L4”, “010” or “L5”, “001” or “L6”, and “000” or “L7”) each corresponding to a respective Vₜ level. For example, the “111” state can be an erased state and each of the other states can be a respective programmed state. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2ⁿ levels of charge to store n bits. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of cells.

A valley margin can also be referred to as a read window. For example, in a SLC cell, there is 1 read window that exists with respect to the 2 Vₜ distributions. Analogously, in an MLC cell, there are 3 read windows that exist with respect to the 4 Vₜ distributions. Similarly, in a TLC cell, there are 7 read windows that exist with respect to the 8 Vₜ distributions. Read window size generally decreases as the number of states increases. For example, the 1 read window for the SLC cell may be larger than each of the 3 read windows for the MLC cell, and each of the 3 read windows for the MLC cell may be larger than each of the 7 read windows for the TLC cell, etc. Read window budget (RWB) refers to the cumulative value of the read windows.

Data retention refers to the ability of a cell to retain its state information over a period of time in an operational state (e.g., powered on state) or a non-operational state (e.g., powered off state). For example, VT distributions can shift due to factors such as time, temperature, program/erase cycles, etc. VT distribution shifts can contribute to read errors, and therefore decrease memory sub-system performance. Additionally, as the VT distribution shifts, the read window budget decreases, thereby becoming more difficult to distinguish between a programmed cell and an erased cell. Data retention can be increasingly more challenging in high temperature environment with even greater impact as the memory device approaches its end-of-life (EOL).

Aspects of the present disclosure address the above and other deficiencies by performing a programming operation on wordlines of an erased block to tighten an erase distribution of the erased block wordlines. An erase operation is typically performed on a block-by-block basis. The wordlines and bitlines of the block are selected and a certain voltage (e.g., an erase voltage) is applied to the wordlines and bitlines of the block until the block is erased. Even though an erase voltage is uniformly applied to all wordlines and bitlines of the block, some wordlines may be deeply erased. Deeply erased wordlines include wordlines in a distribution that is wider and more negatively shifted than the erase distribution of a normally erased wordlines. Deeply erased wordlines can lead to Vt distributions shifting towards more negative values. These Vt distribution shifts may worsen towards the EOL as indicated above.

Accordingly, programming operations on the wordlines of the erased block can be performed if the memory device is near EOL. Determining whether the memory device is near EOL is based on a number of program erase cycles (PECs) encountered by the memory device. If the number of PECs exceeds (or is equal to) a threshold value which indicates that the memory device is near EOL, programming operations may be performed on blocks in which an erase operation is performed. Once it is determined that a block has been erased (e.g., erased block) using an erase operation, a programming operation may be performed on all wordlines of the erased block. The programming operation includes applying a predetermined programming voltage in a single pulse. The programming voltage is high enough to shift a lower tail of an erase distribution associated with a respective wordline, but low enough to maintain the upper tail of the erase distribution. As a result, after the programming operation the erase distribution is tightened.

In some embodiments, the programming operation may be performed on one or more wordlines or wordline groups of the erased block. The one or more wordlines or wordline groups of the erased block may be selected based one or more characteristics of the one or more wordlines or wordline groups of the erased block. For example, the one or more wordlines or wordline groups of the erased block may be selected based on the wordlines or wordline groups that are identified as weak.

In some embodiments, each wordline and/or wordline group of the erased block may be assigned a predetermined programming voltage. For example, each wordline or wordline group may have a level of susceptibility to erase margin degradation. Erase margin degradation refers to a decrease in the difference between an erase distribution of a respective wordline and the Vt distribution of the respective wordline after being programmed. Thus, based on the wordline and/or wordline group of the erased block susceptibility to erase margin degradation a corresponding predetermined programming voltage is used in the programming operation.

Advantages of the present disclosure include, but are not limited to, tightening the erase distribution of various wordlines of the block, decreasing shifts in Vt distributions, and increasing improvement RWB, thereby improving data retention of the memory device.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a program after erase (PAE) component 113 that can tighten an erase distribution of a wordline to improve the RWB towards the end of life of the memory device 130 and/or 140. In some embodiments, the memory sub-system controller 115 includes at least a portion of the PAE component 113. In some embodiments, the PAE component 113 is part of the host system 110, an application, or an operating system. In other embodiments, local media controller 135 includes at least a portion of PAE component 113 and is configured to perform the functionality described herein.

The PAE component 113 determines a number of program erase cycles (PECs) memory device 130 and/or 140 has encountered. The number of PECs represent a number of times the memory device was programmed and then erased. The PAE component 113 determines, based on the number of PECs, whether a condition of the memory device 130 and/or 140 is near an end of life (EOL). The PAE component 113 determines whether the memory device 130 and/or 140 is near the EOL based on whether the number of PECs is greater than or equal to a PEC threshold value indicating that the memory device 130 and/140 is near the EOL. The PAE component 113 enables a program after erase (PAE) mode of the memory device 130 and/140.

The PAE component 113 determines whether an erase operation has been performed on a block of memory device 130 and/or 140. Based on the enablement of the PAE mode, the PAE component 113 performs a programming operation on the wordlines of the erased block. In particular, for each wordline of the block, the PAE component 113 applies a programming voltage in a single pulse to a respective wordline. The programming voltage is a predetermined voltage sufficient (e.g., high) enough to shift a lower tail of an erase distribution associated with the respective wordline and low enough to not shift the upper tail. A shift in the upper tail of the erase distribution may negatively affect an erase margin associated with the respective wordline. The predetermined voltage that causes a shift in the upper tail of the erase distribution indicates a maximum value of the predetermined voltage. As a result of a shift in the lower tail and not the upper tail of the erase distribution associated with the respective wordline, the PAE component 113 tightens the erase distribution of the respective wordline. Tightening of the erase distribution of the respective wordline causes the respective wordline to be less deeply erased (i.e., more normally erased). If the respective wordline is less deeply erased (i.e., more normally erased) the Vt distributions shift is reduced. The reduction in the Vt distribution shift provides RWB improvement.

Depending on the embodiments, the PAE component 113 may perform the programming operation on one or more wordlines or wordline groups of the erased block, instead of all wordlines of the erased block. The PAE component 113 may determine one or more wordlines or wordline groups of the erased block identified as weak (i.e., the one or more wordlines or wordline groups of the erased block with the worse RWB). Thus, the PAE component 113 may perform programming operation on the wordline groups identified as weak using a predetermined programming voltage. While the programming operations is not performed on the remaining wordline groups of the multiple wordline groups not identified as weak.

Depending on the embodiments, the PAE component 113 may perform the programming operation on all wordlines or wordline groups of the erased block. However, rather than using a single predetermined programming voltage for all wordlines or wordline groups, the PAE component 113 determines how susceptible a respective wordline or wordline group is to erase margin degradation. Thus, based on the level of susceptibility (e.g., highly susceptible, mildly susceptible, or negligibly susceptible) to erase margin degradation, a corresponding predetermined programming voltage from a plurality of predetermined programming voltages is used for the programming operation. Erase margin degradation refers to a decrease in the difference between an erase distribution of a respective wordline and the Vt distribution of the respective wordline after being programmed. A higher erase margin means that the erased state and the programmed state are more easily distinguishable, which leads to better read and write performance. A lower erase margin means that the erased state and the programmed state are not easily distinguishable, which leads to more errors. Alternatively, the PAE component 113 may apply the programming operation to all wordlines of the erased block except the one or more wordlines or wordline groups of the erased block that are susceptible to erase margin degradation.

For example, wordlines may be grouped based on their level of susceptibility to erase margin degradation. A wordlines level of susceptibility to erase margin degradation is determined during manufacturing based on testing of the memory device 130 and/or 140 or a similar memory device. Some wordlines that are highly susceptible to erase margin degradation and may be included in a wordline group (e.g., highly susceptible wordline group). Some wordlines that are mildly susceptible to erase margin degradation may be included in a wordline group (e.g., mildly susceptible wordline group). Some wordlines that are negligibly susceptible to erase margin degradation may be included in a wordline group (e.g., negligibly susceptible wordline group). Thus, the PAE component 113 may perform programming operation, using a predetermined programming voltage assigned to highly susceptible wordline group, on wordlines of the highly susceptible wordline group; perform programming operation, using a predetermined programming voltage assigned to mildly susceptible wordline group, on wordlines of the mildly susceptible wordline group; and perform programming operation, using a predetermined programming voltage assigned to negligibly susceptible wordline group, on wordlines of the negligibly susceptible wordline group. As a result, degradation of the erase margin is avoided while reducing the Vt distribution shift and improving the RWB.

Further details with regards to the operations of the PAE component 113 are described below.

FIG. 1B is a simplified block diagram of a first apparatus, in the form of a memory device 130, in communication with a second apparatus, in the form of a memory sub-system controller 115 of a memory sub-system (e.g., the memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

The memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1B) of at least a portion of the array of memory cells 104 are capable of being programmed to one of at least two target data states.

Row decode circuitry 108 and column decode circuitry 111 are provided to decode address signals. Address signals are received and decoded to access the array of memory cells 104. The memory device 130 also includes input/output (I/O) control circuitry 112 to manage input of commands, addresses and data to the memory device 130 as well as output of data and status information from the memory device 130. An address register 114 is in communication with the I/O control circuitry 112 and row decode circuitry 108 and column decode circuitry 111 to latch the address signals prior to decoding. A command register 124 is in communication with the I/O control circuitry 112 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 111 to control the row decode circuitry 108 and column decode circuitry 111 in response to the addresses.

The local media controller 135 is also in communication with a cache register 118 and a data register 121. The cache register 118 latches data, either incoming or outgoing, as directed by the local media controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in the cache register 118 from the I/O control circuitry 112. During a read operation, data can be passed from the cache register 118 to the I/O control circuitry 112 for output to the memory sub-system controller 115; then new data can be passed from the data register 121 to the cache register 118. The cache register 118 and/or the data register 121 can form (e.g., can form at least a portion of) the page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to the memory sub-system controller 115.

The memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various embodiments.

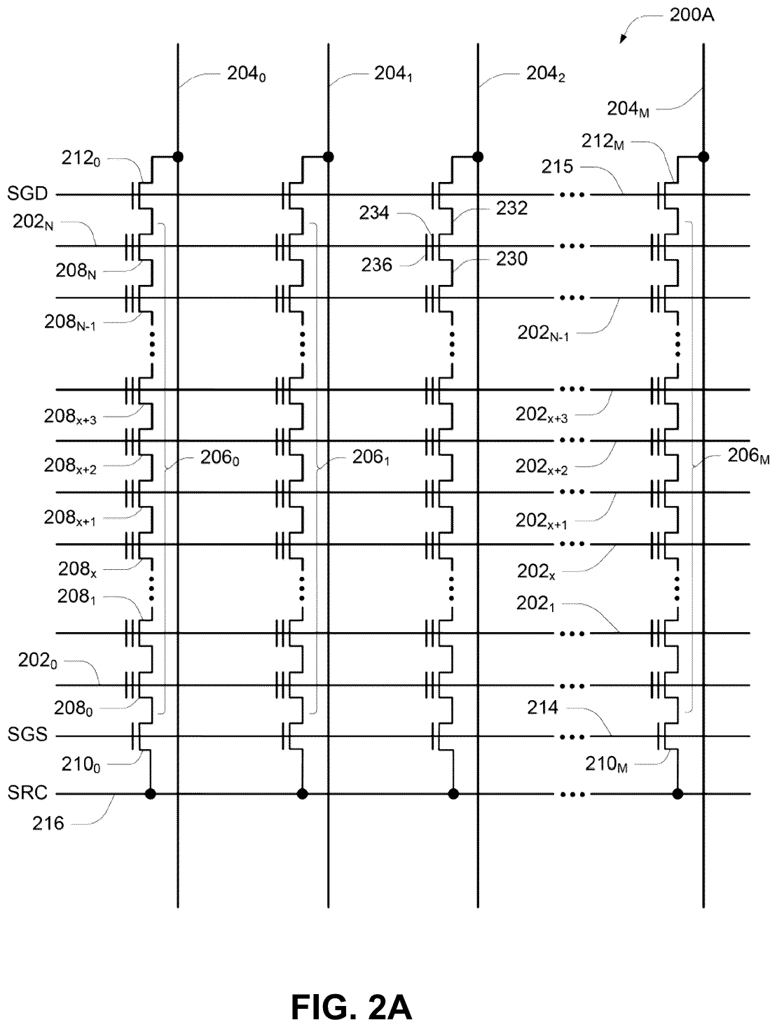

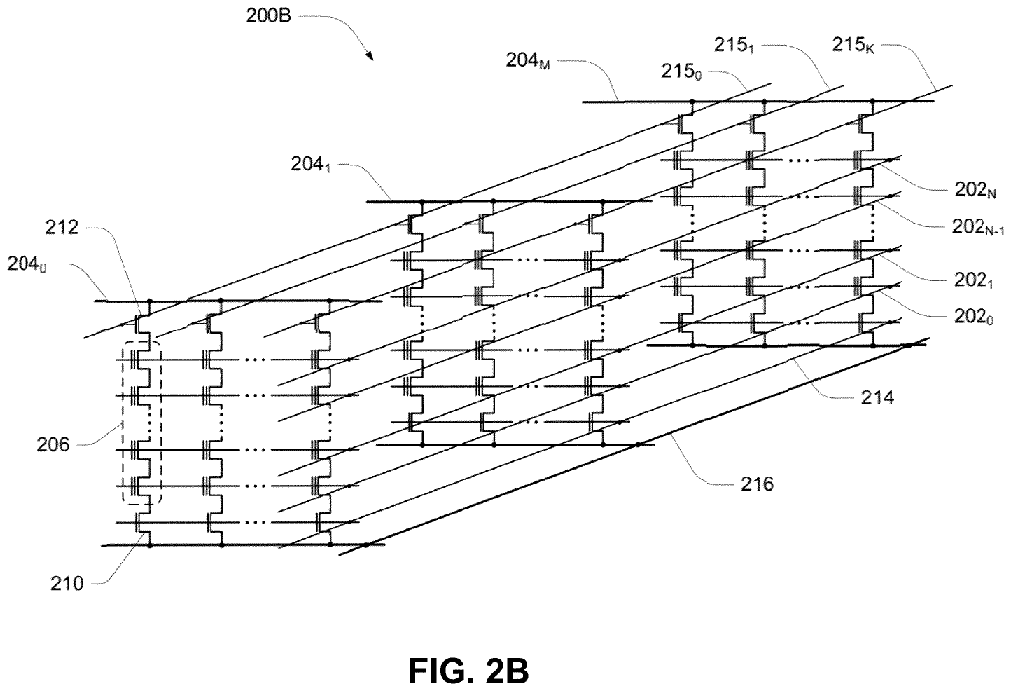

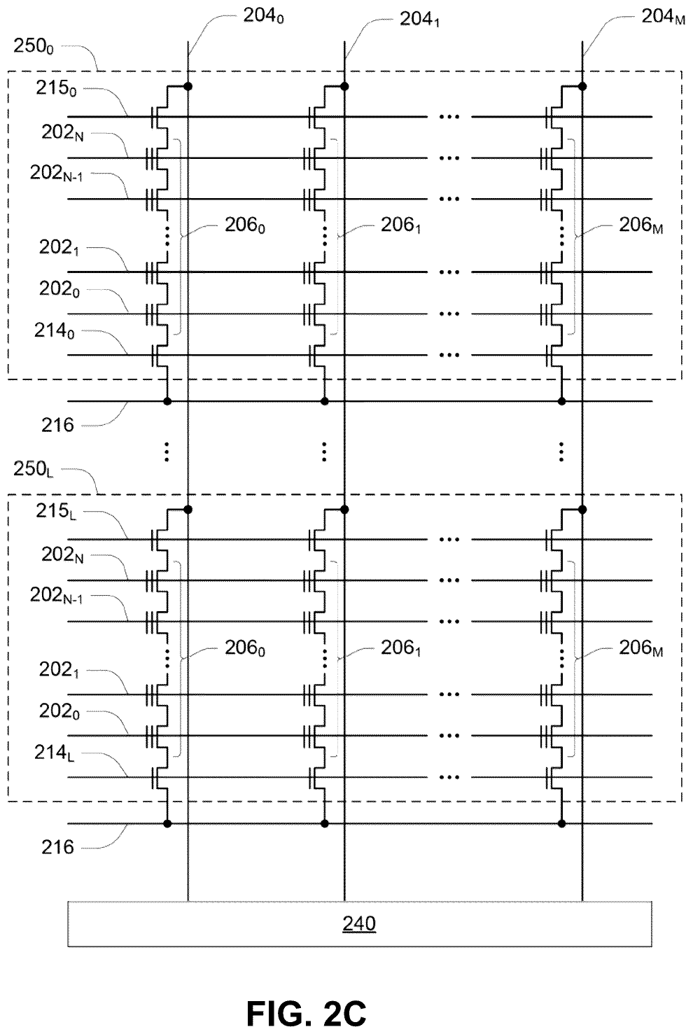

FIG. 2A-2C are schematics of portions of an array of memory cells 200A, such as a NAND memory array, as could be used in a memory of the type described with reference to FIG. 1B according to an embodiment, e.g., as a portion of the array of memory cells 104. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be conductively doped to have a conductivity type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a word line 202.

A column of the memory cells 208 can be a NAND string 206 or a number of NAND strings 206 selectively connected to a given bit line 204. A row of the memory cells 208 can be memory cells 208 commonly connected to a given word line 202. A row of memory cells 208 can, but need not, include all the memory cells 208 commonly connected to a given word line 202. Rows of the memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of the memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory of the type described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B can incorporate vertical structures which can include semiconductor pillars where a portion of a pillar can act as a channel region of the memory cells of NAND strings 206. The NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. Each word line 202 can be connected to multiple rows of memory cells of the memory array 200B. Rows of memory cells that are commonly connected to each other by a particular word line 202 can collectively be referred to as tiers.

FIG. 2C is a further schematic of a portion of an array of memory cells 200C as could be used in a memory of the type described with reference to FIG. 1B, e.g., as a portion of the array of memory cells 104. Like numbered elements in FIG. 2C correspond to the description as provided with respect to FIG. 2A. The array of memory cells 200C can include strings of series-connected memory cells (e.g., NAND strings) 206, access (e.g., word) lines 202, data (e.g., bit) lines 204, select lines 214 (e.g., source select lines), select lines 215 (e.g., drain select lines) and a source 216 as depicted in FIG. 2A. A portion of the array of memory cells 200A can be a portion of the array of memory cells 200C, for example.

FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation, sometimes referred to as erase blocks. Each block of memory cells 250 can represent those NAND strings 206 commonly associated with a single select line 215, e.g., select line 215₀. The source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

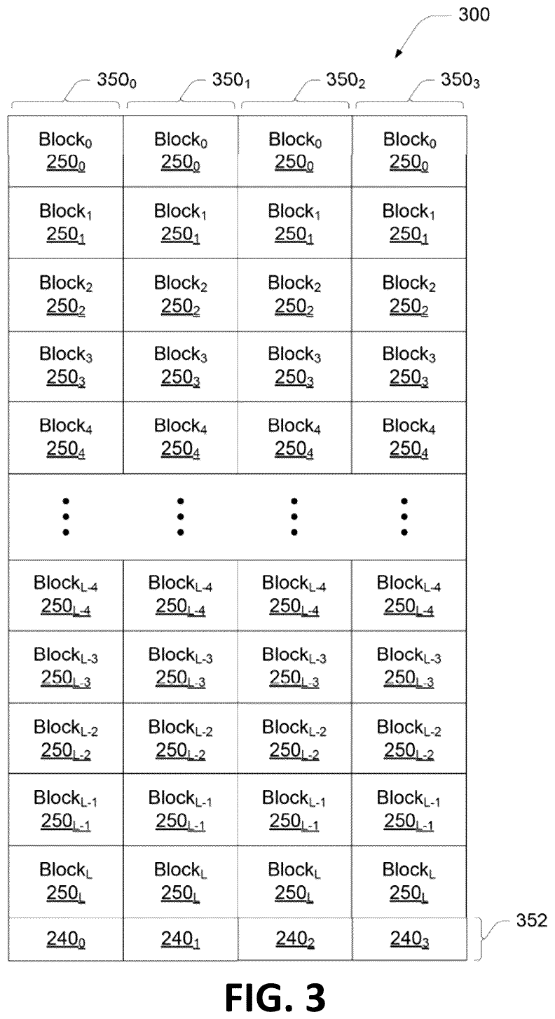

FIG. 3 is a block schematic of a portion of an array of memory cells 300 as could be used in a memory of the type described with reference to FIG. 1B, in accordance with some embodiments of the present disclosure. The array of memory cells 300 is depicted as having four memory planes 350 (e.g., memory planes 350₀-350₃), each in communication with a respective buffer portion 240, which can collectively form a page buffer 352. While four memory planes 350 are depicted, other numbers of memory planes 350 can be commonly in communication with a page buffer 352. Each memory plane 350 is depicted to include L+1 blocks of memory cells 250 (e.g., blocks of memory cells 250₀-250_{L}).

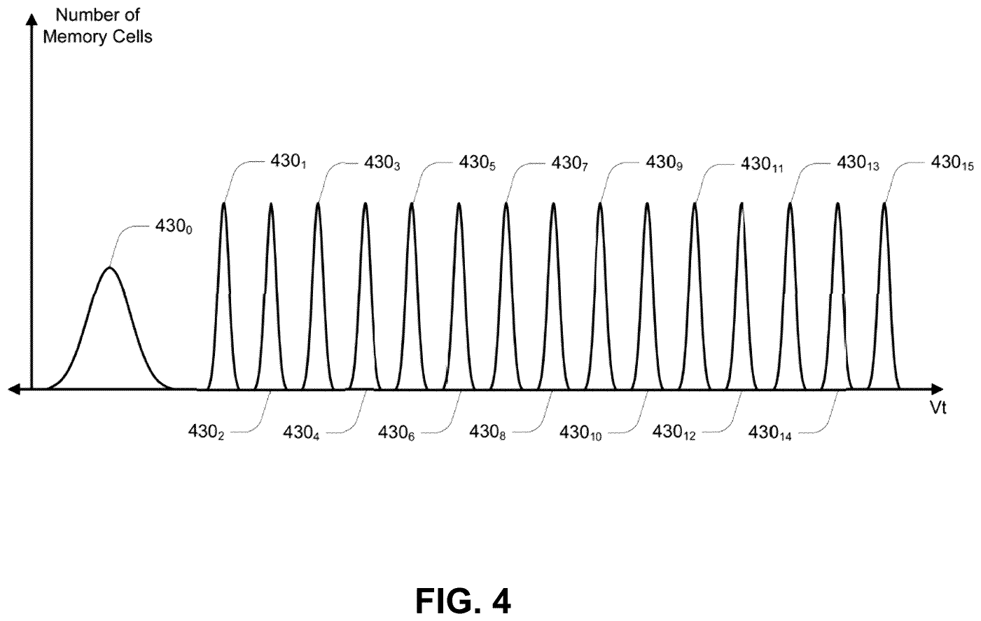

FIG. 4 is a conceptual depiction of threshold voltage ranges of multiple memory cells, in accordance with some embodiments of the present disclosure. FIG. 4 illustrates an example of threshold voltage ranges and their distributions for a population of a sixteen-level memory cells, e.g., QLC memory cells. For example, such a memory cell can be programmed to a threshold voltage (Vt) that falls within one of sixteen different threshold voltage ranges 430₀-430₁₅, each being used to represent a data state corresponding to a bit pattern of four bits. The threshold voltage range 430₀ typically has a greater width than the remaining threshold voltage ranges 430₁-430₁₅ as memory cells are generally all placed in the data state corresponding to the threshold voltage range 430₀, then subsets of those memory cells are subsequently programmed to have threshold voltages in one of the threshold voltage ranges 430₁-430₁₅. As programming operations are generally more incrementally controlled than erase operations, these threshold voltage ranges 430₁-430₁₅ can tend to have tighter distributions.

The threshold voltage ranges 430₀, 430₁, 430₂, 430₃, 430₄, 430₅, 430₆, 430₇, 430₈, 430₉, 430₁₀, 430₁₁, 430₁₂, 430₁₃, 430₁₄, and 430₁₅ can each represent a respective data state, e.g., L0, L1, L2, L3, L4, L5, L6, L7, L8, L9, L10, L11, L12, L13, L14 and L15, respectively. As an example, if the threshold voltage of a memory cell is within the first of the sixteen threshold voltage ranges 430₀, the memory cell in this case can be storing a data state L0 having a data value of logical ‘1111’ and is typically referred to as the erased state of the memory cell. If the threshold voltage is within the second of the sixteen threshold voltage ranges 430₁, the memory cell in this case can be storing a data state L1 having a data value of logical ‘0111’. If the threshold voltage is within the third of the sixteen threshold voltage ranges 430₂, the memory cell in this case can be storing a data state L2 having a data value of logical ‘0011,’ and so on. Table 1 provides one possible correspondence between the data states and their corresponding logical data values. Other assignments of data states to logical data values are known or can be envisioned. Memory cells remaining in the lowest data state (e.g., the erased state or L0 data state), as used herein, will be deemed to be programmed to the lowest data state.

TABLE 1

| Data | Logical |
|---|---|
| State | Data Value |
| L0 | 1111 |
| L1 | 0111 |
| L2 | 0011 |
| L3 | 1011 |
| L4 | 1001 |
| L5 | 0001 |
| L6 | 0101 |
| L7 | 1101 |
| L8 | 1100 |
| L9 | 0100 |
| L10 | 0000 |
| L11 | 1000 |
| L12 | 1010 |
| L13 | 0010 |
| L14 | 0110 |
| L15 | 1110 |

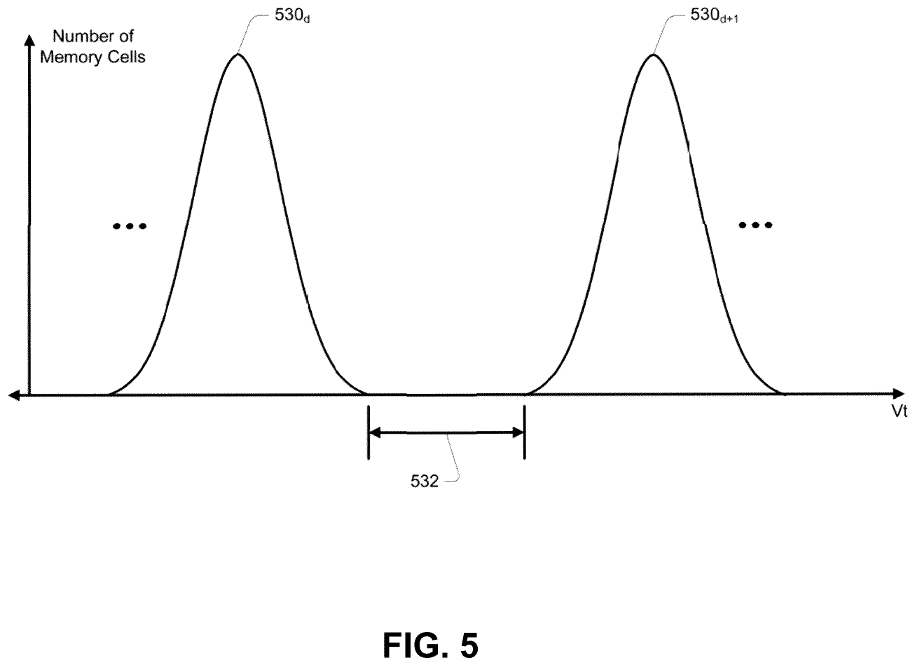

FIG. 5 is a conceptual depiction of a threshold voltage distribution of multiple memory cells following a programming operation, in accordance with some embodiments of the present disclosure. The threshold voltage distributions 530_{d}-530_{d+1} of FIG. 5 can represent some portion of the distributions for threshold voltage ranges 430₀-430₁₅ of FIG. 4 at the completion of a programming operation for memory cells. With reference to FIG. 5, adjacent threshold voltage distributions 530 are typically separated by some margin 532 (e.g., dead space) at the completion of programming. Applying a sense voltage (e.g., read voltage) within the margin 532 to the control gates of the multiple memory cells can be used to distinguish between the memory cells of the threshold voltage distribution 530_{d} (and any lower threshold voltage distribution) and the memory cells of the threshold voltage distribution 530_{d+1} (and any higher threshold voltage distribution).

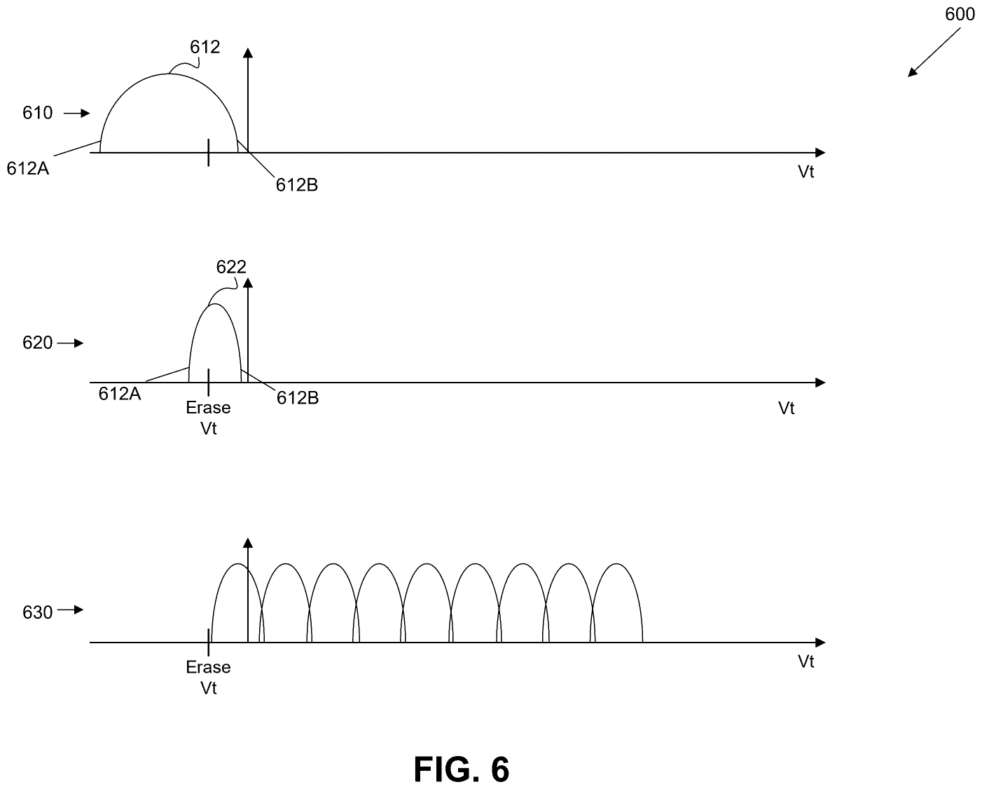

FIG. 6 is a set of graphs 600 illustrating a series of sequential operations for erase distribution tightening to improve read budget window, in accordance with some embodiments of the present disclosure. At operation 610, an erase operation performed on a block produces erase distribution 612 representing the memory cells associated with a wordline of the block. Erase distribution 612 corresponds to an erase distribution of a deeply erased wordline of the block. As previously described, deeply erased wordlines can include wordlines in a distribution that is wider and more negatively shifted than the erase distribution of normally erased wordlines. More specifically, some cells may have faster erase speeds as compared to others (e.g., normal cells). The erase speed may be determined by the memory cell control gate capacitance. The higher the memory cell control gate capacitance, the faster the erase speed. Thus, the distances between a lower tail 612A of the erase distribution 612 and an upper tail 612B of the erase distribution 612 is wider than the distribution for a normally erased wordline. At operation 620, a programming operation is applied to the deeply erased wordline producing a tightened erased distribution 622. The programming operation applies to the deeply erased wordline of the block a predetermined programming voltage. As previously described, in some embodiments, the programming operation is performed on the wordline based on the wordline being identified as weak. In some embodiments, the programming operation may be selected based on a level of susceptibility of the wordline. The predetermined programming voltage is a voltage high enough to shift a lower tail 612A of erase distribution 612 to the right while maintaining the upper tail 612B of erase distribution 612. For example, applying the predetermined programming voltage to the cell results in a tightened distribution. At operation 630, a normal programming operation may be performed on the wordline.

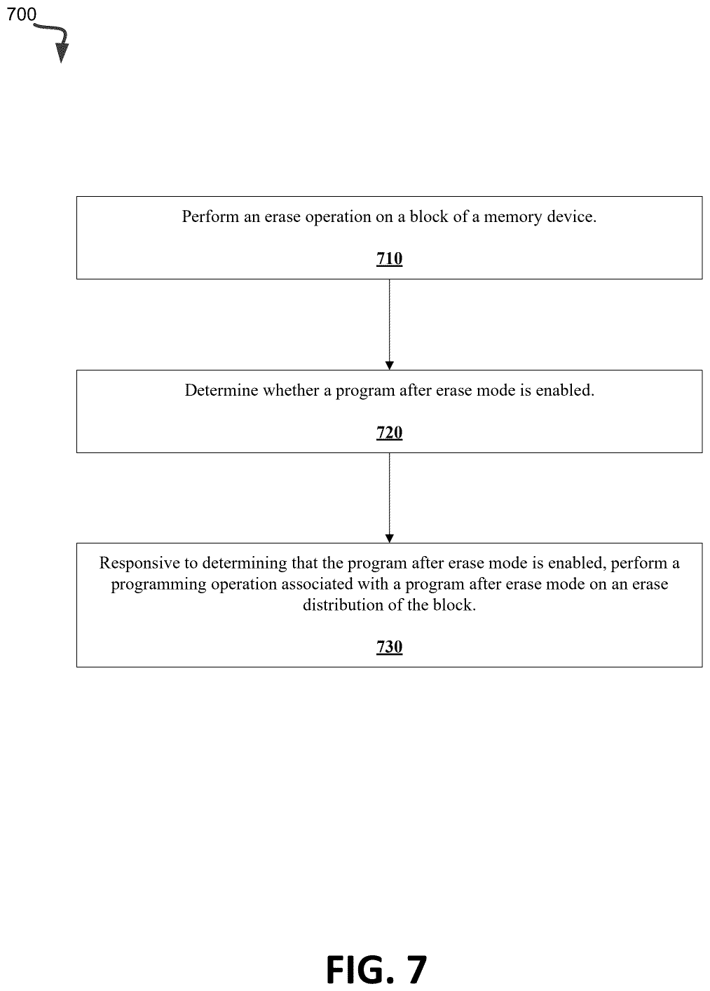

FIG. 7 is a flow diagram of an example method 700 for erase distribution tightening to improve read budget window, in accordance with some embodiments of the present disclosure. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by the PAE component 113 of FIG. 1A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 710, the processing logic performs an erase operation on a block of a memory device. As previously described, the erase operation is performed on the block by selecting the wordlines and bitlines of the block to apply an erase voltage until the block is erased.

At operation 720, the processing logic determines whether a program after erase (PAE) mode is enabled. To determine whether the PAE mode is enabled, prior to or after an erase operation, the processing logic determines a program-erase cycle (PEC) count of the memory device (e.g., number of PECs). The number of PECs are compared to a PEC threshold value. The PEC threshold value is associated with an end of life condition of the memory device. If the number of PEC is greater than or equal to a PEC threshold value then a PEC criterion is satisfied, otherwise the PEC criterion is not satisfied. If the PEC criterion is satisfied, the PAE mode is enabled, otherwise the PAE mode is not enabled.

At operation 730, responsive to determining that the program after erase mode is enabled, the processing logic performs a programming operation associated with a program after erase mode on an erase distribution of the block. As previously described, some wordlines may be deeply erased. The predetermined programming voltage is applied to one or more wordline or wordline group of the block (e.g., a respective wordline or wordline group) in a single pulse.

In some embodiments, for each wordline group of a plurality of wordline groups of the block, the processing logic identifies a corresponding (or respective) predetermined programming voltage associated with a respective wordline group and performs the programming operation by applying the corresponding predetermined programming voltage to the respective wordline group. As previously described, wordlines may be grouped based on their level of susceptibility to erase margin degradation. Thus, each level of susceptibility to erase margin degradation has a corresponding predetermined voltage level. Accordingly, based on a level of susceptibility to erase margin degradation of the wordline or wordline group the corresponding predetermined programming voltage is selected to be used for performing the programming operation.

In some embodiments, the processing logic identifies, from a plurality of wordline groups of the block, a subset of wordline groups identified as weak wordline groups and performs the programming operation on the subset by applying a predetermined programming voltage to each wordline of the subset of wordline groups. As previously described, a programming operation is not performed on the remaining wordline groups of the plurality of wordline groups.

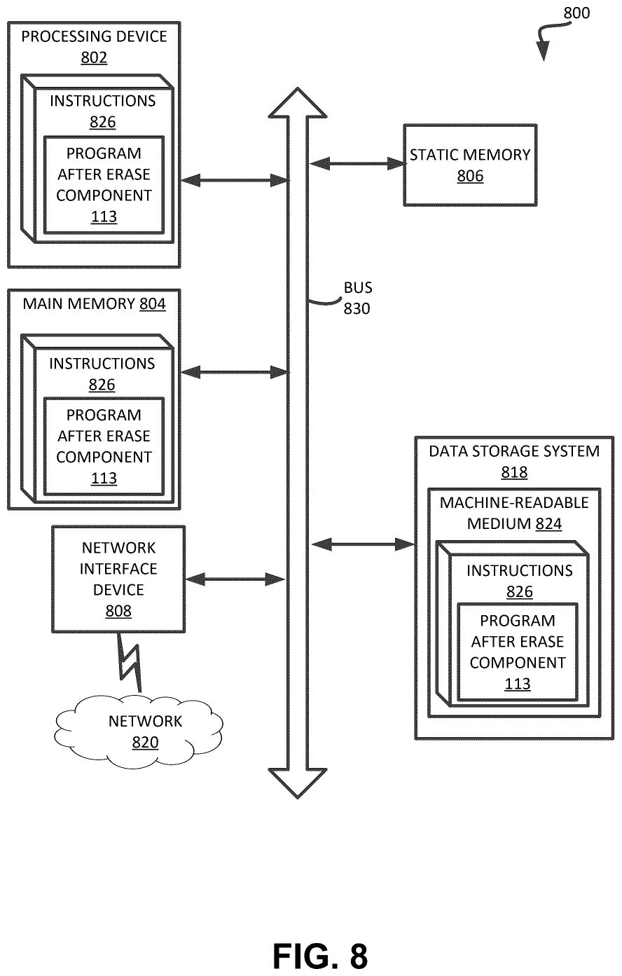

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the PAE component 113 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or RDRAM, etc.), a static memory 806 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 826 for performing the operations and steps discussed herein. The computer system 800 can further include a network interface device 808 to communicate over the network 820.

The data storage system 818 can include a machine-readable storage medium 824 (also known as a computer-readable medium) on which is stored one or more sets of instructions 826 or software embodying any one or more of the methodologies or functions described herein. The instructions 826 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 110 of FIG. 1A.

In one embodiment, the instructions 826 include instructions to implement functionality corresponding to a PAE component (e.g., the PAE component 113 of FIG. 1A). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
performing an erase operation on a block of a memory device;
determining whether a program after erase mode is enabled; and
responsive to determining that the program after erase mode is enabled, performing a programming operation associated with the program after erase mode on an erase distribution of the block.

2. The method of claim 1, wherein determining that the program after erase mode is enabled comprises:
determining a program-erase cycle (PEC) count of the memory device;
determining whether the PEC satisfies a PEC criterion; and
responsive to determining that the PEC satisfies the PEC criterion, enabling the program after erase mode.

3. The method of claim 2, wherein the determining that the PEC satisfies the PEC criterion comprises determining that the PEC is greater than or equal to a PEC threshold value of the PEC criterion.

4. The method of claim 3, wherein the PEC threshold value is associated with an end of life condition of the memory device.

5. The method of claim 1, wherein performing the programming operation on the erase distribution of the block comprises:
for each wordline group of a plurality of wordline groups of the block, identifying a respective predetermined programming voltage associated with a respective wordline group; and
causing the respective predetermined programming voltage to be applied to the respective wordline group.

6. The method of claim 5, wherein the respective predetermined programming voltage is applied to the respective wordline group in a single pulse.

7. The method of claim 1, wherein performing the programming operation on the erase distribution of the block comprises:
identifying, from a plurality of wordline groups of the block, a subset of wordline groups identified as weak wordline groups; and
causing a predetermined programming voltage to be applied to the subset of wordline groups.

8. A system comprising:
a memory device; and
a processing device, operatively coupled with the memory device, to perform operations comprising:
performing an erase operation on a block of the memory device;
determining whether a program after erase mode is enabled; and
responsive to determining that the program after erase mode is enabled, performing a programming operation associated with the program after erase mode on an erase distribution of the block.

9. The system of claim 8, wherein determining that the program after erase mode is enabled comprises:
determining a program-erase cycle (PEC) count of the memory device;
determining whether the PEC satisfies a PEC criterion; and
responsive to determining that the PEC satisfies the PEC criterion, enabling the program after erase mode.

10. The system of claim 9, wherein the determining that the PEC satisfies the PEC criterion comprises determining that the PEC is greater than or equal to a PEC threshold value of the PEC criterion.

11. The system of claim 10, wherein the PEC threshold value is associated with an end of life condition of the memory device.

12. The system of claim 8, wherein performing the programming operation on the erase distribution of the block comprises:
for each wordline group of a plurality of wordline groups of the block, identifying a respective predetermined programming voltage associated with a respective wordline group; and
causing the respective predetermined programming voltage to be applied to the respective wordline group.

13. The system of claim 12, wherein the respective predetermined programming voltage is applied to the respective wordline group in a single pulse.

14. The system of claim 8, wherein performing the programming operation on the erase distribution of the block comprises:
identifying, from a plurality of wordline groups of the block, a subset of wordline groups identified as weak wordline groups; and
causing a predetermined programming voltage to be applied to the subset of wordline groups.

15. A non-transitory computer-readable storage medium comprising instructions that, when executed by a processing device, cause the processing device to perform operations comprising:
performing an erase operation on a block of a memory device;
determining whether a program after erase mode is enabled; and
responsive to determining that the program after erase mode is enabled, performing a programming operation associated with the program after erase mode on an erase distribution of the block.

16. The non-transitory computer-readable storage medium of claim 15, wherein determining that the program after erase mode is enabled comprises:
determining a program-erase cycle (PEC) count of the memory device;
determining whether the PEC satisfies a PEC criterion; and
responsive to determining that the PEC satisfies the PEC criterion, enabling the program after erase mode.

17. The non-transitory computer-readable storage medium of claim 16, wherein the determining that the PEC satisfies the PEC criterion comprises determining that the PEC is greater than or equal to a PEC threshold value of the PEC criterion.

18. The non-transitory computer-readable storage medium of claim 17, wherein the PEC threshold value is associated with an end of life condition of the memory device.

19. The non-transitory computer-readable storage medium of claim 15, wherein performing the programming operation on the erase distribution of the block comprises:
for each wordline group of a plurality of wordline groups of the block, identifying a respective predetermined programming voltage associated with a respective wordline group; and
causing the respective predetermined programming voltage to be applied to the respective wordline group in a single pulse.

20. The non-transitory computer-readable storage medium of claim 15, wherein performing the programming operation on the erase distribution of the block comprises:
identifying, from a plurality of wordline groups of the block, a subset of wordline groups identified as weak wordline groups; and
causing a predetermined programming voltage to be applied to the subset of wordline groups.
